(19) United States
(12) Patent Application Publication
(10) Pub. No.: US 2004/0129965 A1
(43) Pub. Date: Jul. 8, 2004

(54) Trench capacitor process for preventing parasitic leakage

(76) Inventor: Shih-Fang Chen, Hsinchu (TW)

Correspondence Address: BIRCH STEWART KOLASCH & BIRCH, PO BOX 747, FALLS CHURCH, VA, 22040-0747, US

(21) Appl. No.: 10/404,430

(22) Filed: Apr. 2, 2003

(30) Foreign Application Priority Data
Jan. 8, 2003 (TW) 092100341

(51) Int. Cl. H01L 27/108

(52) U.S. Cl. 257/301

(57) ABSTRACT

A trench capacitor process for preventing parasitic leakage. The process is capable of blocking leakage current from a parasitic transistor adjacent to the trench, and includes forming a doping layer and a cap layer covering on part of the sidewall of the trench and performing an annealing process on the doping layer and forming a dopant region in the substrate adjacent to the sidewall of the trench, blocking leakage current from a parasitic transistor adjacent to the trench.

### BACKGROUND OF THE INVENTION

1. Field of the Invention

The present invention relates to a semiconductor device and the process thereof, and in particularly to a trench capacitor for preventing parasitic leakage adjacent to trench capacitors in DRAM cells and the process thereof.

2. Description of the Related Art

Dynamic random access memory (DRAM), a kind of semiconductor memory, consists of a storage capacitor and an access transistor in each cell that can achieve higher integration, is widely used in computers and electronic devices.

Nevertheless, charges stored in the capacitors decrease with time, resulting from an inherent leakage current, so DRAM cells must be refreshed before the stored charges fall below their operational threshold voltage (Vₜₕ).

Trench capacitor is a typical structure used in DRAM cells, whose storage capacity can be increased through enlarging the depth of the trench, providing larger surface area.

In FIG. 1, a layout is shown for conventional trench capacitors. Trench capacitors 10 are disposed under passing wordlines 12. Access transistors 14 are electrically coupled to storage nodes 16 of trench capacitors 10 through diffusion regions 18. Diffusion regions 20 are also included, being electrically connected to contacts 22. Contacts 22 connect to bitline (not shown) to read and write to storage nodes 16 through access transistors 14. Access transistors 14 are activated by wordlines 12. When voltage is applied to wordlines 12, a channel therebelow allows current between diffusion regions 18 and 20 and into or out of storage nodes 16.

In FIG. 2, a cross-section along the A-A′ phantom line in FIG. 1 is shown to illustrate a conventional trench capacitor employing n-channel MOSFET. At this point, trench capacitor 10 is formed in a substrate 24 and the trench is typically filled with polysilicon to form a storage node 16 doped with n-type dopants. Buried plate 26 is also doped with n-type dopants and surrounds the lower portion of the trench. Node dielectric 28 separates storage node 16 and buried plate 26. Storage node 16 and P-well PW, including p-dopants are electrically isolated by dielectric collars 30. Buried well 32, including n-type dopants, is provided to connect buried plate 26 adjacent to the trench capacitor 10.

Diffusion region 18 of access transistor 14 is connected to storage node 16 by a node diffusion region 34. When trench capacitor 10 is completely formed, shallow trench isolation (STI) 38 is then formed in substrate and part of trench capacitor 10 to define an active area and to isolate trench capacitor 10 and a passing wordline 12′ formed later. Wordlines 12 and the STI 38 can then be used as implant masks forming diffusion regions 18 and 20 which may be a source and drain of access transistor 14.

During the operation of trench capacitor 10, a vertical parasitic transistor will typically be formed on the sidewall of the trench in region 40 of FIG. 2, located in the p-well PW between node diffusion region 34 and buried plate 24.

The region 40 in FIG. 2 is further enlarged and rotated 90 degrees counterclockwise in FIG. 3 for illustration. At this point, the above-mentioned parasitic transistor includes node diffusion region 34 and buried well 32 as its source and drain (respectively). When an appropriate charge is stored within the capacitor, storage node 16 acts as a gate and dielectric collar 30 will acts as a gate dielectric, and then a channel 42 will be formed in p-well PW within the substrate and charges stored in a trench capacitor can pass through this channel 42 and form a parasitic leakage current, resulting in increased frequency to refresh the storage capacitor and affect charge storage performance.

### SUMMARY OF THE INVENTION

Accordingly, an object of the invention is to provide a trench capacitor process to reduce the parasitic leakage adjacent to a trench capacitor.

Furthermore, the present invention provides a trench capacitor process for preventing parasitic leakage, comprising providing a substrate with a trench formed therein, having a buried plate formed adjacent to the trench, forming a dielectric layer and a first conductive layer in the lower portion of the trench, wherein the buried plate and the first conductive layer are separated by the dielectric layer, forming a doping layer and a cap layer sequentially, covering on part of the sidewall of the trench exposed by the dielectric layer and the first conductive layer, performing an annealing process on the doping layer, forming a dopant region in the substrate adjacent to the sidewall of the trench to block leakage current from a parasitic transistor formed adjacent to the trench, forming a second conductive layer contacting the first conductive layer in the trench, etching out the doping layer and the cap layer exposed by the second conductive layer until exposing part of the sidewalls of the trench and forming a third conductive layer on the second conductive layer and finally filling the trench, wherein the third conductive layer directly contacts the sidewall of the trench.

In brief, the present invention provides a trench capacitor process for preventing parasitic leakage, capable of blocking leakage current resulting from a parasitic transistor formed adjacent to the trench, comprising forming a doping layer and a cap layer covering part of the sidewall of the trench and performing an annealing process on the doping layer and forming a dopant region in the substrate adjacent to the sidewall of the trench to block leakage current resulting from a parasitic transistor formed adjacent to the trench.

In the trench capacitor process for preventing parasitic leakage in accordance to the present invention, the material of the doping layer can be BSG and the material of the cap layer can be silicon dioxide. Using an annealing process such as furnace annealing or rapid thermal annealing (RTA), the dopants (Boron) in the doping layer are driven into the substrate adjacent to the trench capacitor and doping regions vertically distributed in the substrate adjacent to the trench and approximately equidistant from the trench are formed. The charging conductivity of the dopants in these doping regions is the same as in the substrate and the concentration of the dopants in the doping region is about double that in the substrate. The threshold voltage of a parasitic transistor nearby the dopant region is thus elevated and the parasitic leakage path controlled by the parasitic transistor is not turned on easily. The leakage associated with the vertical parasitic device is suppressed by the dopant region of the invention. The retention time of a trench capacitor is elevated, the frequency for refreshing DRAM cells is reduced, and the storage performance of a trench capacitor is promoted.

In addition, the dielectric collar in the art can be replaced by the doping layer and the cap layer formed on the sidewall of the trench in the invention and the sequence of the trench capacitor process need not be changed. The cap layer can further be removed to reduce the thickness of the dielectric collar to meet certain process targets and add design flexibility and suitable process window to the memory cell design.

Furthermore, the methods in the invention are widely used in the semiconductor industry so there is no need for retooling. Thus, the trench capacitor process of the invention can be slightly modified from the existing process and adopted quickly to reduce parasitic leakage in trench capacitors, such that the overall performance of the DRAM cells is improved.

In addition, a trench capacitor with a adjacent parasitic leakage channel in accordance with the invention comprises a node diffusion and a buried well in the substrate adjacent to a trench capacitor as a source or drain, a dual-layered dielectric layer on a sidewall of the trench capacitor as a gate dielectric and electrically contacting the node diffusion and the buried well, a conductive layer on the dielectric layer forming a parasitic transistor adjacent to the trench capacitor and a dopant region in the substrate between the node diffusion and the buried well elevating a threshold voltage for turning on a parasitic leakage channel of the parasitic transistor.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a layout of conventional trench capacitors in the Prior Art;

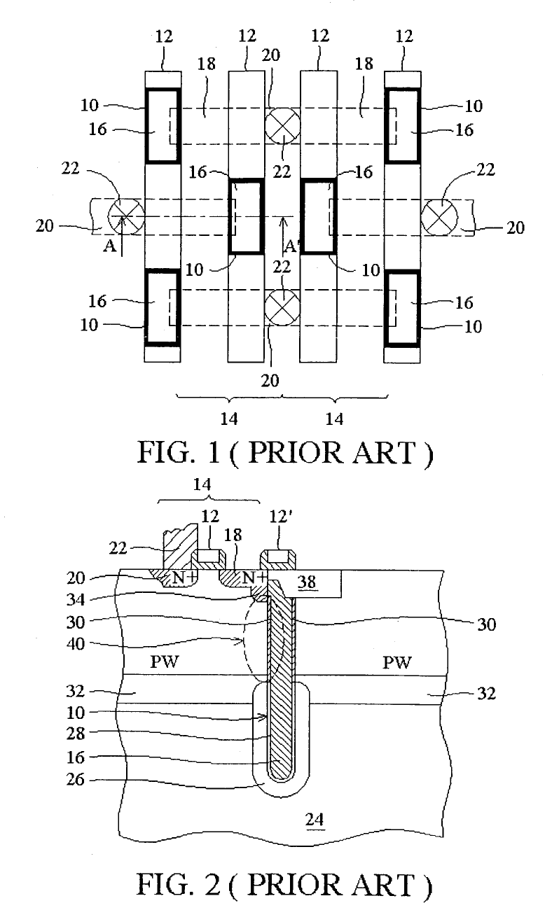

FIG. 2 is a cross-section along the A-A′ phantom line in FIG. 1;

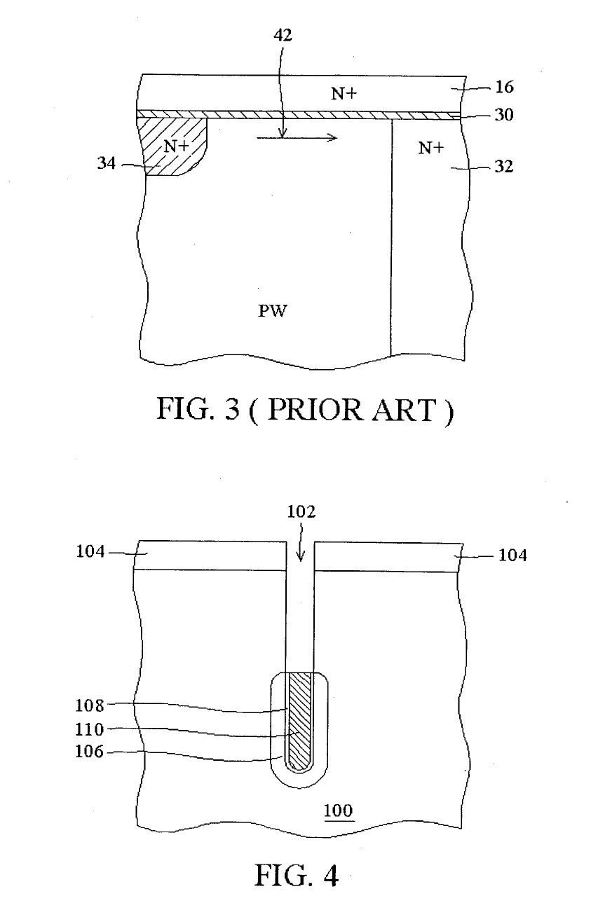

FIG. 3 is an enlarged view of region 40 in FIG. 2;

FIGS. 4-10 are cross-sections of a trench capacitor process of the invention;

FIG. 11 is an enlarged view of region 150 in FIG. 9;

FIG. 12 is a comparison between leakage current reduction in a parasitic transistor of the invention and in the Prior Art.

### DETAILED DESCRIPTION OF THE INVENTION

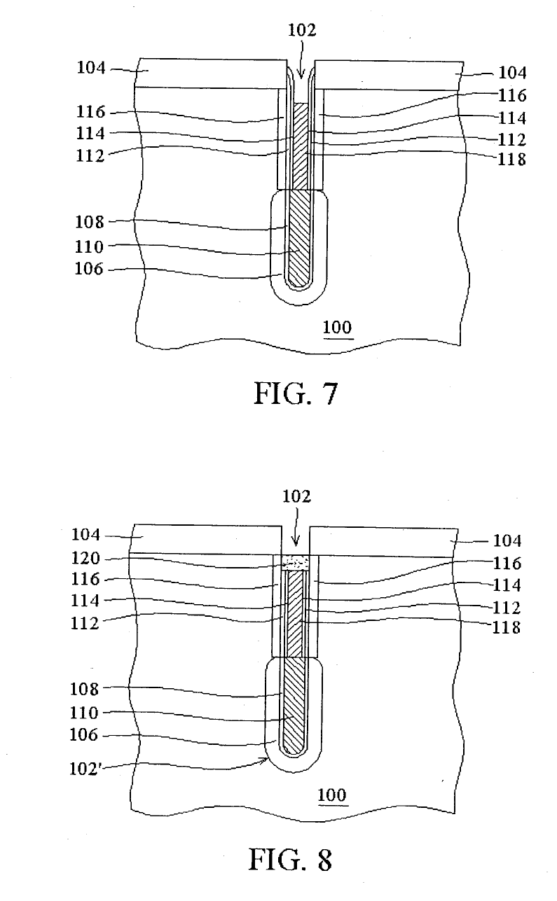

The trench capacitor process for preventing parasitic leakage in accordance with the present invention is illustrated in FIG. 4 to FIG. 10.

In FIG. 4, a substrate 100 with a trench 102 formed therein is provided and includes a pad stack 104 formed thereon. Substrate 100 illustratively includes a p-substrate, however n-substrates may be used with appropriately charging conductivities.

Pad stack 104 may include one or more layers of dielectric material, such as silicon dioxide or silicon nitride. Pad stack 104 is opened at the location where trench 102 is to be placed. Trench 102 is formed by etching substrate 100 through pad stack 104. Trench 102 is preferably formed using a reactive ion etch (RIE) process. A buried plate 106 resulting from an n-doped region is formed in the lower portion of trench 102 by known methods.

A conformal layer of dielectric material is deposited in trench 102. The dielectric material preferably includes nitride, such as silicon nitride. Trench 102 is then filled is with a conductive material and the material in the trench is partially removed by a recess process and a first conductive layer 110 is formed in the lower portion of trench 102. The dielectric material exposed by the first conductive layer 108 is then removed and leaves a dielectric layer 108, wherein buried plate 106 and first conductive layer 110 are separated by the dielectric layer 108. The first conductive layer 110 is preferably n-doped polysilicon and more preferably arsenic-doped polysilicon. The recess process used for removing the conductive material is preferably dry etching and the method for removing the exposed dielectric material is preferably wet etching.

In FIG. 5, a layer of doping material, such as boro-silicate-glass (BSG), and a layer of cap material, such as silicon dioxide, are sequentially deposited on the surface of pad stack 104 and in trench 102 through plasma enhanced chemical vapor deposition (PECVD) and low pressure chemical vapor deposition (LPCVD) respectively. An etch-back process is then performed and a doping layer 112 and a cap layer 114 covering part of the sidewall of trench 102 uncovered by dielectric layer 108 and the first conductive layer 110 are formed. The charging conductivity of the dopants in doping layer 112 is the same as in substrate 100. The thickness of the doping layer 112 and the cap layer are about 200-400 angstroms and 200 angstroms respectively. A high temperature annealing process applied on the doping layer 112 is then performed and dopants such as boron in the doping Layer 112 are sealed by the cap layer 114 and diffuse merely toward the substrate 100 on both sides of the trench 102. This high temperature annealing process can be furnace annealing or rapid thermal annealing (RTA).

In FIG. 6, through the high temperature annealing process mentioned, dopant regions 116 are formed in substrate 100 adjacent to sidewalls of the trench 102. Dopant regions 116 are vertically distributed in substrate 100 adjacent to and approximately equidistant from the trench 102. Through the above-mentioned annealing process, the concentration of the p-type dopants in doping regions 116 can be increased to a concentration of 4×10¹³ atoms/cm² and is about double that in the substrate 100 (typically about 2×10¹³ atoms/cm²).

In FIG. 7, trench 102 is then filled with a subsequent conductive material and the conductive material is etched back by known methods. A second conductive layer 110 that contacts the first conductive layer 110 is then formed in trench 102.

In FIG. 8, the doping layer 112 and the cap layer 114 exposed by the second conductive layer 118 are etched out and part of sidewalls of the trench 102 is exposed. Trench 102 is then re-filled with a conductive material forming a third conductive layer 120 that fills trench 102 and contacts the second conductive layer 118 and the trench 102 directly by a conventional recess process. The surface of the third conductive layer is about the same height to the surface of substrate 100. The second conductive layer 118 and the third conductive layer 120 are preferably n-doped polysilicon and, more preferably, arsenic-doped polysilicon.

Here, a charge storage node consisting of the first, second and third conductive layer is formed. A trench capacitor 102′ is then formed by matching the storage node with dielectric layer 108, buried plate 112 and cap layer 114. The composite film of the doping layer 112 and the cap layer 114 in the invention can also perform electrical isolation between a storage node and the p-well, thus replacing the dielectric collar in the Prior Art.

In FIG. 9, buried well 122 comprising n-type dopants is then formed in substrate 100 outside the trench capacitor 102′ by known methods, connecting the buried plate 106 adjacent to the trench capacitor 102′. A shallow trench isolation (STI) 124 is then formed in the substrate and part of the trench capacitor 102′ to define active area and to isolate the trench capacitor 102′ from passing wordline 126′ formed later, thus combining with wordline 126 and passing wordline 126′ to act as implant masks for forming diffusion regions 128 and 130, which may be a source and drain of the access transistor 140. Diffusion region 130 of the access transistor 140 is connected to a storage node (as shown a third conductive layer 120 here) by node diffusion region 132. A DRAM cell consisting of a trench capacitor 102′ and a access transistor 140 is then completely formed.

Furthermore, to satisfy certain process issues, cap layer 114 covering the doping layer 112 can optionally be removed by an adequate etching process, such as wet etching, after annealing, to reduce the overall thickness of the composite layer and forming a DRAM cell consisting of a trench capacitor 102′ and an access transistor 140 through the above-mentioned process. The structure is shown in FIG. 10 for illustration.

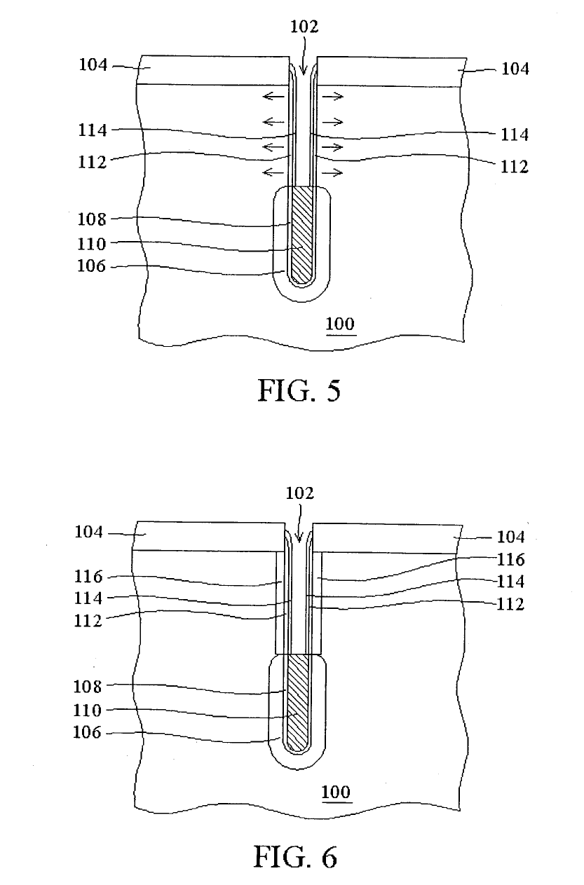

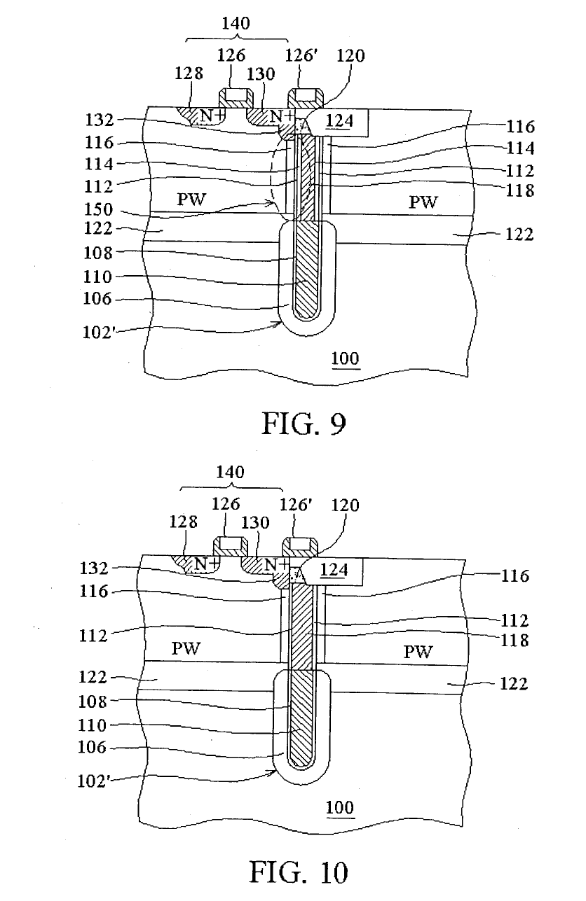

The region 150 in FIG. 9 is further enlarged and rotated 90 degrees counterclockwise in FIG. 11 for illustration. At this point, the above-mentioned parasitic transistor includes node diffusion 132 and buried well 122 as its source and drain (respectively). Storage node (shown as the second conductive layer 118 here) acts as a gate and the doping layer 112 and the cap layer 114 act as a dual-layered gate dielectric. Through the trench capacitor process in accordance with present invention, a dopant region 116 with the same charging conductivity as the p-well PW is formed, a higher threshold voltage (Vₜₕ) is needed for turning on the channel 160 here than for turning the channel 42 in FIG. 3 where no dopant region exists.

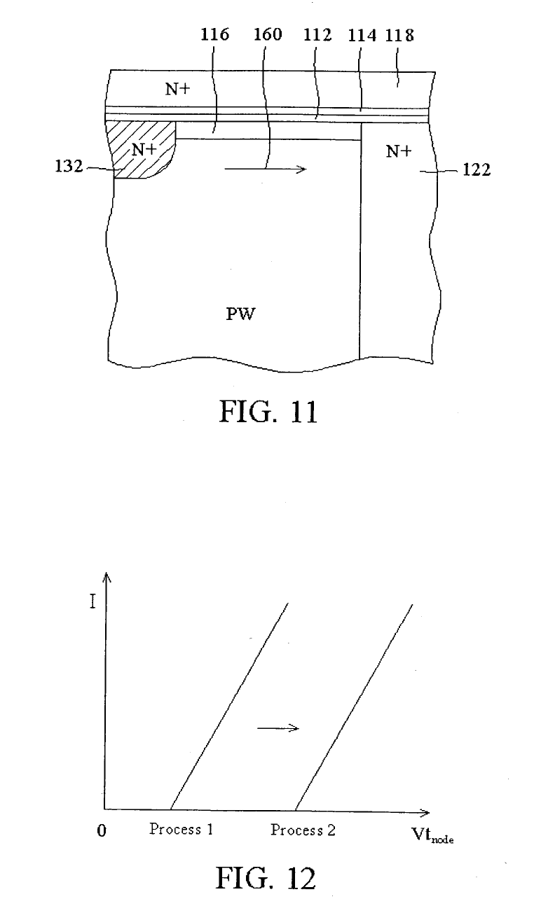

In FIG. 12, a comparison of leakage current (I) reduction of a parasitic transistor in the invention and in the Prior art is shown. The threshold voltage for turning on a parasitic transistor is referred to as Vt_{node} hereinafter. By comparing the conventional trench capacitor formed in the art (shown as process 1) with the trench capacitor formed in accordance with the present invention (shown as process 2), the Vt_{node} in process 2 is elevated, making the channel 160 in FIG. 11 more difficult to turn on, so the charges stored in a trench capacitor achieve better performance, the retention time of the trench capacitor is promoted, and DRAM refresh frequency can be reduced, such that the storage performance of trench capacitors is promoted.

Compared with the Prior Art, the present invention has the following advantages.

First, in the dopant regions formed adjacent to sidewalls of a trench capacitor in accordance with the prevent invention, the concentration of the p-dopants is doubled that in the substrate, so the threshold voltage of a parasitic transistor near this region is elevated and the parasitic leakage path controlled by the parasitic transistor is not turned on easily. The leakage current associated with the vertical parasitic device is suppressed by the dopant region in the invention. The retention time of a trench capacitor is elevated, the DRAM refresh frequency is reduced, and the storage performance of a trench capacitor is promoted.

Second, the dielectric collar in the art can be replaced by the doping layer and the cap layer formed on the sidewall of the trench in the invention and the sequence of the trench capacitor process need not be changed. The cap layer can further be removed to reduce the thickness of the dielectric collar, meeting certain process issues and add design flexibility and suitable process window to the memory cell design.

Third, the manufacturing methods in the invention are widely used in the semiconductor industry such that there is no need for retooling. Thus, the trench capacitor process of the invention can be slightly modified from the existing process and adopted quickly and easily to reduce the parasitic leakage in trench capacitors and the overall performance of the DRAM cells is improved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A trench capacitor process for preventing parasitic leakage, comprising:
providing a substrate with a trench formed therein, the trench having a buried plate formed adjacent to the trench;
forming a dielectric layer and a first conductive layer in the lower portion of the trench, wherein the buried plate and the first conductive layer are separated by the dielectric layer;
forming a doping layer and a cap layer sequentially, covering the part of the sidewall of the trench exposed by the dielectric layer and the first conductive layer;
performing an annealing process on the doping layer, forming a dopant region in the substrate adjacent to the sidewall of the trench to block leakage current resulting from a parasitic transistor adjacent to the trench;
forming a second conductive layer contacting the first conductive layer in the trench, etching out the doping layer and the cap layer exposed by the second conductive layer until exposing part of the sidewalls of the trench; and
forming a third conductive layer on the second conductive layer and filling the trench, wherein the third conductive layer directly contacts the sidewall of the trench.

2. The trench capacitor process as claimed in claim 1, further comprising removing the cap layer before forming the second conductive layer.

3. The trench capacitor process as claimed in claim 2, wherein the method used for removing the cap layer is wet etching.

4. The trench capacitor process as claimed in claim 1, wherein the substrate is p-substrate.

5. The trench capacitor process as claimed in claim 1, wherein the dielectric layer is nitride material.

6. The trench capacitor process as claimed in claim 5, wherein the nitride material is silicon nitride.

7. The trench capacitor process as claimed in claim 1, wherein the buried plate is a n-doped region in the substrate adjacent to the lower portion of the trench.

8. The trench capacitor process as claimed in claim 1, wherein the first conductive layer, the second conductive layer and the third conductive layer are n-doped polysilicon.

9. The trench capacitor process as claimed in claim 8, wherein the n-doped polysilicon is arsenic-doped polysilicon.

10. The trench capacitor process as claimed in claim 1, wherein the doping layer is boro-silicate-glass (BSG).

11. The trench capacitor process as claimed in claim 1, wherein the cap layer is silicon dioxide.

12. The trench capacitor process as claimed in claim 1, wherein the doping region is vertically distributed in the substrate adjacent to the trench and approximately equidistant from the trench.

13. The trench capacitor process as claimed in claim 1, wherein the annealing process is furnace annealing or rapid thermal annealing (RTA).

14. The trench capacitor process as claimed in claim 1, wherein the charging conductivity of the dopants in the doping region is the same as in the substrate.

15. The trench capacitor process as claimed in claim 1, wherein the concentration of the dopants in the doping region is about double that in the substrate.

16. A trench capacitor process for preventing parasitic leakage, capable of blocking leakage current resulting from a parasitic transistor adjacent to the trench, comprising:
forming a doping layer and a cap layer covering on part of the sidewall of the trench; and
performing an annealing process on the doping layer and forming a dopant region in the substrate adjacent to the sidewall of the trench to block leakage current resulting from a parasitic transistor adjacent to the trench.

17. The trench capacitor process as claimed in claim 16, wherein the doping layer is boro-silicate-glass (BSG).

18. The trench capacitor process as claimed in claim 16, wherein the cap layer is silicon dioxide.

19. The trench capacitor process for preventing parasitic leakage as claimed in claim 16, wherein the charging conductivity of the dopants in the doping region is the same as in the substrate.

20. The trench capacitor process as claimed in claim 16, wherein the concentration of the dopants in the doping region is about double that in the substrate.

21. A trench capacitor with a adjacent parasitic leakage channel comprising:
a node diffusion and a buried well in the substrate adjacent to a trench capacitor as a source or drain;
a dual-layered dielectric layer on a sidewall of the trench capacitor as a gate dielectric and electrically contacting the node diffusion and the buried well;
a conductive layer on the dielectric layer forming a parasitic transistor adjacent to the trench capacitor; and
a dopant region in the substrate between the node diffusion and the buried well elevating a threshold voltage for turning on a parasitic leakage channel of the parasitic transistor.

22. The trench capacitor as claimed in claim 21, wherein the charging conductivity of the dopants in the doping region is the same as in the substrate.

23. The trench capacitor as claimed in claim 21, wherein the concentration of the dopants in the doping region is about double that in the substrate.
